(19) United States
(12) Patent Application Publication
(10) Pub. No.: US 2025/0021714 A1
(43) Pub. Date: Jan. 16, 2025

(54) GENERATING SIMULATION ENVIRONMENTS FOR TESTING AUTONOMOUS VEHICLE BEHAVIOUR

(71) Applicant: Five AI Limited, Cambridge (GB)

(72) Inventors: Iain Whiteside, Cambridge (GB); Monal Narasimhamurthy, Cambridge (GB)

(73) Assignee: Five AI Limited, Cambridge (GB)

(21) Appl. No.: 18/712,054

(22) PCT Filed: Nov. 2, 2022
(86) PCT No.: PCT/EP2022/080559

§ 371 Date: May 21, 2024

(30) Foreign Application Priority Data
Nov. 22, 2021 (GB) 2116775.4

(51) Int. Cl. G06F 30/15

(52) U.S. Cl. CPC G06F 30/15

(57) ABSTRACT

For generating driving scenarios for testing an autonomous vehicle planner in a simulation environment, a scenario model comprises a scenario variable and a distribution associated with the scenario variable. The scenario variable is a road layout variable. Multiple sampled values of the scenario variable are computed based on the distribution associated the scenario variable. Based on the scenario model, multiple driving scenarios are generated for testing an autonomous vehicle planner in a simulation environment, each driving scenario comprising a road layout generated using a sampled value of said multiple sampled values of the scenario variable.

### TECHNICAL FIELD

The present disclosure relates to the generation of scenarios for use in simulation environments for testing the behaviour of autonomous vehicles.

### BACKGROUND

There have been major and rapid developments in the field of autonomous vehicles. An autonomous vehicle (AV) is a vehicle which is equipped with sensors and control systems which enable it to operate without a human controlling its behaviour to varying degrees. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. There are different facets to testing the behaviour of the sensors and control systems aboard a particular autonomous vehicle, or a type of autonomous vehicle. A distinction is sometimes drawn between planning (higher-level decision making) and control (lower-level implementation of those decisions); it is noted the term “control system” is used in a general sense and includes planning systems (or planning and control systems) in this sense.

An autonomous vehicle may be fully autonomous (in that it is designed to operate with no human supervision or intervention, at least in certain circumstances) or semi-autonomous. Semi-autonomous systems require varying levels of human oversight and intervention. An Advanced Driver Assist System (ADAS) and certain levels of Autonomous Driving System (ADS) may be classed as semi-autonomous.

A “level 5” vehicle is one that can operate entirely autonomously in any circumstances, because it is always guaranteed to meet some minimum level of safety. Such a vehicle would not require manual controls (steering wheel, pedals etc.) at all. By contrast, level 3 and level 4 vehicles can operate fully autonomously but only within certain defined circumstances (e.g. within geofenced areas).

A level 3 vehicle must be equipped to autonomously handle any situation that requires an immediate response (such as emergency braking); however, a change in circumstances may trigger a “transition demand”, requiring a driver to take control of the vehicle within some limited timeframe. A level 4 vehicle has similar limitations; however, in the event the driver does not respond within the required timeframe, a level 4 vehicle must also be capable of autonomously implementing a “minimum risk maneuver” (MRM), i.e. some appropriate action(s) to bring the vehicle to safe conditions (e.g. slowing down and parking the vehicle).

A level 2 vehicle requires the driver to be ready to intervene at any time, and it is the responsibility of the driver to intervene if the autonomous systems fail to respond properly at any time. With level 2 automation, it is the responsibility of the driver to determine when their intervention is required; for level 3 and level 4, this responsibility shifts to the vehicle's autonomous systems, and it is the vehicle that must alert the driver when intervention is required.

Sensor processing may be evaluated in real-world physical facilities. Similarly, the control systems for autonomous vehicles may be tested in the physical world, for example by repeatedly driving known test routes, or by driving routes with a human on-board to manage unpredictable or unknown context.

Physical world testing will remain an important factor in the testing of autonomous vehicles' capability to make safe and predictable decisions. However, physical world testing is expensive and time-consuming. Increasingly there is more reliance placed on testing using simulated environments. If there is to be an increase in testing in simulated environments, it is desirable that such environments can reflect as far as possible real-world scenarios. Autonomous vehicles need to have the facility to operate in the same wide variety of circumstances that a human driver can operate in. Such circumstances can incorporate a high level of unpredictability.

It is not viable to achieve from physical testing a test of the behaviour of an autonomous vehicle in all possible scenarios that it may encounter in its driving life. Increasing attention is being placed on the creation of simulation environments which can provide such testing in a manner that gives confidence that the test outcomes represent potential real behaviour of an autonomous vehicle.

For effective testing in a simulation environment, the autonomous vehicle under test (the ego vehicle) has knowledge of its location at any instant of time, understands its context (based on simulated sensor input) and can make safe and predictable decisions about how to navigate its environment to reach a pre-programmed destination.

Simulation environments need to be able to represent real-world factors that may change. This can include weather conditions, road types, road structures, road layout, junction types etc. This list is not exhaustive, as there are many factors that may affect the operation of an ego vehicle.

The present disclosure addresses the particular challenges which can arise in simulating the behaviour of actors in the simulation environment in which the ego vehicle is to operate. Such actors may be other vehicles, although they could be other actor types, such as pedestrians, animals, bicycles et cetera.

A simulator is a computer program which when executed by a suitable computer enables a sensor equipped vehicle control module to be developed and tested in simulation, even before its physical counterpart is built and tested. A simulator provides a three-dimensional environmental model which reflects the physical environment that an automatic vehicle may operate in. The 3D environmental model defines at least the road network on which an autonomous vehicle is intended to operate, and (typically) other actor(s) in the environment. In addition to modelling the behaviour of the ego vehicle, the behaviour of these actors also needs to be modelled. A full “sensor realistic” simulator provides a sensor simulation system which models each type of sensor with which the autonomous vehicle may be equipped and provides synthetic sensor data (e.g. image, radar, lidar etc.) to a stack under testing. Other forms of simulation do not require sensor models or synthetic sensor data. For example, an AV planner (or a planner in combination with a controller) might be tested on lower-fidelity inputs derived from the simulation, without the direct use of a perception system.

Simulators generate test scenarios (or handle scenarios provided to them). As already explained, there are reasons why it is important that a simulator can produce many different scenarios in which the ego vehicle can be tested. Such scenarios can include different behaviours of actors. The large number of factors involved in each decision to which an autonomous vehicle must respond, and the number of other requirements imposed on those decisions (such as safety and comfort as two examples) mean it is not feasible to write a scenario for every single situation that needs to be tested. Nevertheless, attempts must be made to enable simulators to efficiently provide as many scenarios as possible, and to ensure that such scenarios are close matches to the real world. If testing done in simulation does not generate outputs which are faithful to the outputs generated in the corresponding physical world environment, then the value of simulation is markedly reduced.

Scenarios may be created from live scenes which have been recorded in real life driving. It may be possible to mark such scenes to identify real driven paths and use them for simulation. Test generation systems can create new scenarios, for example by taking elements from existing scenarios (such as road layout and actor behaviour) and combining them with other scenarios. Scenarios may additionally or alternatively be randomly generated.

However, there is increasingly a requirement to tailor scenarios for particular circumstances such that particular sets of factors can be generated for testing. It is desirable that such scenarios may define actor behaviour.

### SUMMARY

Consideration has been given to ‘abstract’ driving scenarios that are defined in terms of road network topologies that can be matched to existing geometric road layouts or maps in some map database. A dynamic interaction defined on a given topology can be realized on different road layouts matching the topology. In practice, this is challenging to implement for more complex scenarios, and is limited by the coverage of the maps database. The latter may be addressed by increasing the number of available maps, but comprehensive coverage would come at the expense of significantly increased storage requirements and resource requirements for each search.

‘Synthetic’ maps may be generated programmatically, in contrast to ‘real’ maps obtained by mapping real world spaces. There are various ways in which synthetic maps could be incorporated in AV testing. For example, a map database could be augmented with synthetic maps, with the aim of increasing the coverage of the map database. However, this approach suffers from the drawbacks noted above.

The present disclosure provides tools and methods for programmatically generating synthetic maps in a targeted and flexible manner, whilst still providing comprehensive testing coverage.

A first aspect herein provides a computer system for generating driving scenarios for testing an autonomous vehicle planner in a simulation environment, the computer system comprising: one or more processors; and a memory coupled to the one or more processors, the memory embodying computer-readable instructions, which, when executed on the one or more processors, cause the one or more processors to: receive a scenario model comprising a scenario variable and a distribution associated with the scenario variable, compute multiple sampled values of the scenario variable based on the distribution associated the scenario variable, and based on the scenario model, generate multiple driving scenarios for testing an autonomous vehicle planner in a simulation environment, each driving scenario generated using a sampled value of said multiple sampled values of the scenario variable.

In the described embodiments, a scenario model is constructed using a probabilistic domain-specific language (DSL) that allows any combination of deterministic and/or probabilistic constraints to be placed on any desired combination of scenario variables that describe not only the road layout but also dynamic agent behaviour.

In embodiments, the scenario variable may be a road layout variable, the value of which is used to generate a road layout of the scenario.

The scenario variable may be a dynamic agent variable, pertaining to a dynamic agent of the scenario.

The computer system may comprise a user interface operable to display images, wherein the computer-readable instructions cause the one or more processors to render an image of each driving scenario of the multiple driving scenarios at the user interface.

The computer-readable instructions may cause the one or more processors to create the scenario model according to received model creation inputs.

The model creation inputs may be received at the user interface.

The computer-readable instructions may cause the one or more processors to: receive model modification inputs, modify the scenario model according to the model modification inputs, and generate multiple further driving scenarios based on the modified scenario model.

Modifying the scenario may comprise modifying the distribution associated with the scenario variable, wherein the computer-readable instructions may cause the one or more processors to: compute multiple further sampled values of the scenario variable based on the modified distribution, and generate multiple further driving scenarios based on the modified scenario model, each further driving scenario generated using a further sampled value of the multiple further sampled values of the scenario variable.

The scenario model may comprise a second scenario variable and one of: a deterministic value associated with the second scenario variable, wherein each driving scenario of the multiple driving scenarios is generated using the deterministic value of the second scenario variable, a second distribution associated with the second scenario variable, wherein the multiple driving scenarios are generated using respective second sampled values of the second scenario variable computed based on the second distribution.

The scenario model may comprise a second scenario variable and an intermediate variable, wherein the distribution may be assigned to the intermediate variable, and the scenario variable and the second scenario variable may be defined in terms of the intermediate variable. The computer-readable instructions may cause the one or more processors to: sample multiple intermediate values of the intermediate variable from the distribution defined assigned to the intermediate variable, and compute multiple second sampled values of the second scenario variable. Each driving scenario may be generated using: (i) the sampled value of said multiple sampled values of the scenario variable, that sampled value of the scenario variable being computed from an intermediate value of the multiple intermediate values of the intermediate variable, and (ii) a second sampled value of said multiple second sampled values of the second scenario variable, that second sampled value of the second scenario variable being computed from the same intermediate value of the intermediate variable.

The computer-readable instructions may cause the one or more processors to: use each driving scenario of the multiple driving scenarios to generate a simulation environment, in which an ego agent is controlled by an autonomous vehicle planner user testing, and thereby generate a set of test results for assessing performance of the autonomous vehicle planner in the simulation environment.

The scenario model may comprise multiple scenario variables and multiple distributions, each distribution associated with at least one scenario variable.

The multiple scenario variables may comprise a road layout variable and a dynamic agent variable.

The scenario model may define a relationship between the dynamic agent variable and the road layout variable, the relationship imposing a constraint on values that may be sampled from the distribution associated with the dynamic agent variable or the road layout variable.

The computer system may comprise an autonomous vehicle (AV) planner to be tested and a simulator coupled to the AV planner, the simulator configured to run each driving scenario and determine a behaviour of an ego agent in each driving scenario to implement decisions taken by the AV planner under testing.

A second aspect herein provides a computer-implemented method of testing an autonomous vehicle (AV) planner in a simulation environment, the method comprising:

accessing a scenario model, the scenario model comprising a set of scenario variables and a set of constraints associated therewith, the set of scenario variables comprising one or more road layout variables; sampling a set of values of the set of scenario variables based on one or more distributions associated with the set of scenario variables, subject to the set of constraints; generating a scenario from the set of values, the scenario comprising a synthetic road layout defined by the value(s) of the one or more road layout variables; and testing the AV planner by running the scenario in a simulator, the simulator controlling an ego agent to implement decisions taken by a planner of the AV planner for autonomously navigating the synthetic road layout.

The scenario model may comprise a dynamic agent variable, the sampling step further comprising sampling a value of the dynamic agent variable, the simulator controlling behaviour of another agent based on the value of the dynamic agent variable.

The set of constraints may comprise a defined relationship between a dynamic variable and a road layout variable.

The method may comprise identifying and mitigating, based on the testing, an issue in the AV planner or a component tested in combination with the AV planner (such as a controller, prediction system or perception system).

Another aspect herein provides program instructions configured to implement any of the method steps or system functionality taught herein.

### BRIEF DESCRIPTION OF FIGURES

Particular embodiments will now be described, by way of example only, with reference to the following schematic figures, in which:

FIG. 1A shows a schematic function block diagram of an autonomous vehicle stack;

FIG. 1B shows a schematic overview of an autonomous vehicle testing paradigm;

FIG. 2 shows a schematic block diagram of a testing pipeline;

FIG. 3A shows a schematic block diagram of a visualization component for rendering a graphical user interface on which real-world or simulation test results are displayed;

FIG. 3B shows a view available within a graphical user interface for accessing real-world or simulation test results;

FIG. 4 shows a function block diagram of a computer system for generating scenario models;

FIG. 5 shows a schematic block diagram of a scenario generation and simulation pipeline, in which scenarios are generated and provided to a simulator based on predetermined scenario models;

FIGS. 6A-G shows different views of a graphic user interface for constructing and previewing scenario models to be used in subsequent simulation testing.

### DETAILED DESCRIPTION

Whether real or simulated, a scenario requires an ego agent to navigate a real or modelled physical context. The ego agent is a real or simulated mobile robot that moves under the control of the stack under testing. The physical context includes static and/or dynamic element(s) that the stack under testing is required to respond to effectively. For example, the mobile robot may be a fully or semi-autonomous vehicle under the control of the stack (the ego vehicle). The physical context may comprise a static road layout and a given set of environmental conditions (e.g. weather, time of day, lighting conditions, humidity, pollution/particulate level etc.) that could be maintained or varied as the scenario progresses. A dynamic scenario additionally includes one or more other agents (“external” agent(s), e.g. other vehicles, pedestrians, cyclists, animals etc.).

The following description draws a distinction between a “scenario model”, a “scenario” and a “scenario run” (or instance).

A “scenario model” defines a class of scenarios probabilistically, in terms of one or more distributions associated with scenario variable(s) from which value(s) of those scenario variable(s) may be sampled. In the described implementation, a scenario model is defined by a scenario specification that is coded in a probabilistic, domain-specific language (DSL), referred to herein as “scenario DSL”. A scenario variable that can take different values with probabilities defined by a distribution is referred to as a probabilistic variable for conciseness. Scenario variables may describe characteristics of the road layout (e.g. number of lanes, lane characteristics, curvature, markings, surface type etc.) as well as dynamic agent(s) (e.g. agent lane, agent type, starting position, motion characteristics etc.)

A “scenario” is consumed by a simulator and may be generated from a scenario model by sampling value(s) of any probabilistic scenario variables of the scenario model. A single scenario model can be used to generate multiple scenarios, with different sampled value(s). In the described implementation, a scenario is represented as a scenario description that may be provided to a simulator as input. A scenario description may be encoded using a scenario description language (SDL), or in any other form that can be consumed by whichever component(s) require it. For example, a road network of a scenario may be stored in a format such as ASAM OpenDRIVE®, and ASAM OpenSCENARIO® may be used to describe dynamic content. Other forms of scenario description may be used, including bespoke languages and formats, and the present techniques are not limited to any particular SDL, storage format, schema or standard. Note the distinction between the (probabilistic) DSL used to define scenario models and the SDL used to describe concrete scenarios.

A “scenario run” or “scenario instance” refers to a concrete occurrence of an agent(s) navigating a physical context, optionally in the presence of one or more other agents. A single scenario can give rise to multiple simulated runs, with different outcomes, not least because those outcomes depend on decisions taken by the stack under testing. The terms “run” and “instance” are used interchangeably in this context.

As a user of scenarios, it would be desirable to actively explore different road aspects of an operational design domain (ODD) for a given scenario. A known approach to this would be via synthetic map generation that could take an ODD and/or a road topology and generate maps that cover it. These could then be paired with scenarios to execute broad coverage.

### Example AV Stack:

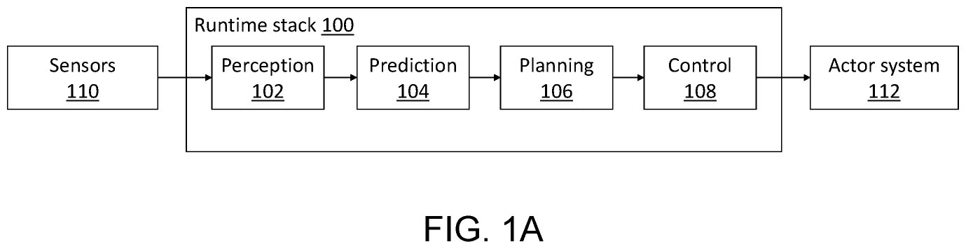

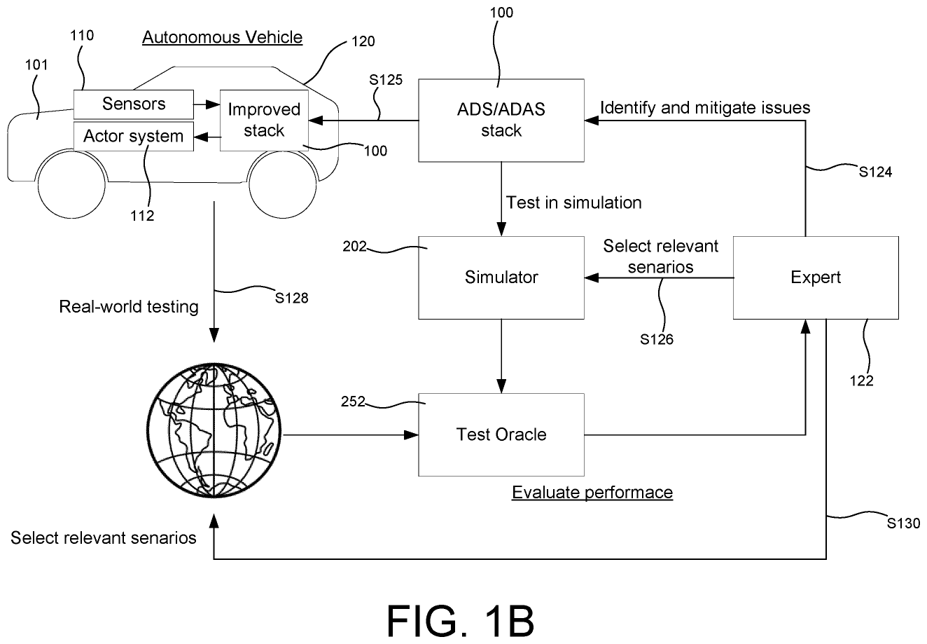

FIG. 1A shows a highly schematic block diagram of an AV runtime stack 100. The stack 100 may be fully or semi-autonomous. For example, the stack 100 may operate as an Autonomous Driving System (ADS) or Advanced Driver Assist System (ADAS).

The run time stack 100 is shown to comprise a perception (sub-) system 102, a prediction (sub-) system 104, a planning (sub-) system (planner) 106 and a control (sub-) system (controller) 108.

In a real-world context, the perception system 102 receives sensor outputs from an on-board sensor system 110 of the AV, and uses those sensor outputs to detect external agents and measure their physical state, such as their position, velocity, acceleration etc. The on-board sensor system 110 can take different forms but generally comprises a variety of sensors such as image capture devices (cameras/optical sensors), lidar and/or radar unit(s), satellite-positioning sensor(s) (GPS etc.), motion/inertial sensor(s) (accelerometers, gyroscopes etc.) etc. The onboard sensor system 110 thus provides rich sensor data from which it is possible to extract detailed information about the surrounding environment, and the state of the AV and any external actors (vehicles, pedestrians, cyclists etc.) within that environment. The sensor outputs typically comprise sensor data of multiple sensor modalities such as stereo images from one or more stereo optical sensors, lidar, radar etc. Sensor data of multiple sensor modalities may be combined using filters, fusion components etc.

The perception system 102 typically comprises multiple perception components which co-operate to interpret the sensor outputs and thereby provide perception outputs to the prediction system 104.

In a simulation context, depending on the nature of the testing—and depending, in particular, on where the stack 100 is “sliced” for the purpose of testing (see below)—it may or may not be necessary to model the on-board sensor system 100. With higher-level slicing, simulated sensor data is not required therefore complex sensor modelling is not required.

The perception outputs from the perception system 102 are used by the prediction system 104 to predict future behaviour of external actors (agents), such as other vehicles in the vicinity of the AV.

Predictions computed by the prediction system 104 are provided to the planner 106, which uses the predictions to make autonomous driving decisions to be executed by the AV in a given driving scenario. The inputs received by the planner 106 would typically indicate a drivable area and would also capture predicted movements of any external agents (obstacles, from the AV's perspective) within the drivable area. The driveable area can be determined using perception outputs from the perception system 102 in combination with map information, such as an HD (high definition) map.

A core function of the planner 106 is the planning of trajectories for the AV (ego trajectories), taking into account predicted agent motion. This may be referred to as trajectory planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner 116, also referred to as a goal generator 116.

The controller 108 executes the decisions taken by the planner 106 by providing suitable control signals to an on-board actor system 112 of the AV. In particular, the planner 106 plans trajectories for the AV and the controller 108 generates control signals to implement the planned trajectories. Typically, the planner 106 will plan into the future, such that a planned trajectory may only be partially implemented at the control level before a new trajectory is planned by the planner 106. The actor system 112 includes “primary” vehicle systems, such as braking, acceleration and steering systems, as well as secondary systems (e.g. signalling, wipers, headlights etc.).

The example of FIG. 1A considers a relatively “modular” architecture, with separable perception, prediction, planning and control systems 102-108. The sub-stack themselves may also be modular, e.g. with separable planning modules within the planning system 106. For example, the planning system 106 may comprise multiple trajectory planning modules that can be applied in different physical contexts (e.g. simple lane driving vs. complex junctions or roundabouts). This is relevant to simulation testing for the reasons noted above, as it allows components (such as the planning system 106 or individual planning modules thereof) to be tested individually or in different combinations. For the avoidance of doubt, with modular stack architectures, the term stack can refer not only to the full stack but to any individual sub-system or module thereof.

The extent to which the various stack functions are integrated or separable can vary significantly between different stack implementations—in some stacks, certain aspects may be so tightly coupled as to be indistinguishable. For example, in other stacks, planning and control may be integrated (e.g. such stacks could plan in terms of control signals directly), whereas other stacks (such as that depicted in FIG. 1A) may be architected in a way that draws a clear distinction between the two (e.g. with planning in terms of trajectories, and with separate control optimizations to determine how best to execute a planned trajectory at the control signal level). Similarly, in some stacks, prediction and planning may be more tightly coupled. At the extreme, in so-called “end-to-end” driving, perception, prediction, planning and control may be essentially inseparable. Unless otherwise indicated, the perception, prediction planning and control terminology used herein does not imply any particular coupling or modularity of those aspects.

A “full” stack typically involves everything from processing and interpretation of low-level sensor data (perception), feeding into primary higher-level functions such as prediction and planning, as well as control logic to generate suitable control signals to implement planning-level decisions (e.g. to control braking, steering, acceleration etc.). For autonomous vehicles, level 3 stacks include some logic to implement transition demands and level 4 stacks additionally include some logic for implementing minimum risk maneuvers. The stack may also implement secondary control functions e.g. of signalling, headlights, windscreen wipers etc.

The term “stack” can also refer to individual sub-systems (sub-stacks) of the full stack, such as perception, prediction, planning or control stacks 104, 106, 108, which may be tested individually or in any desired combination. A stack can refer purely to software, i.e. one or more computer programs that can be executed on one or more general-purpose computer processors. It will be appreciated that the term “stack” encompasses software, but can also encompass hardware. In simulation, software of the stack may be tested on a “generic” off-board computer system, before it is eventually uploaded to an on-board computer system of a physical vehicle. However, in “hardware-in-the-loop” testing, the testing may extend to underlying hardware of the vehicle itself. For example, the stack software may be run on the on-board computer system (or a replica thereof) that is coupled to the simulator for the purpose of testing. In this context, the stack under testing extends to the underlying computer hardware of the vehicle. As another example, certain functions of the stack 110 (e.g. perception functions) may be implemented in dedicated hardware. In a simulation context, hardware-in-the loop testing could involve feeding synthetic sensor data to dedicated hardware perception components.

Within the stack 100, a scenario description 116 may be used as a basis for planning and prediction. The scenario description 116 is generated using the perception system 102, together with a high-definition (HD) map 114. By localizing the ego vehicle 114 on the map, it is possible to combine the information extracted in the perception system 104 (including dynamic agent information) with the pre-existing environmental information contained in the HD map 114. The scenario description 116 is, in turn, used as a basis for motion prediction in the prediction system 104, and the resulting motion predictions 118 are used in combination with the scenario description 116 as a basis for planning in the planning system 106.

### Example Testing Paradigm:

FIG. 1B shows a highly schematic overview of a testing paradigm for autonomous vehicles. An ADS/ADAS stack 100, e.g. of the kind depicted in FIG. 1A, is subject to repeated testing and evaluation in simulation, by running multiple scenario instances in a simulator 202, and evaluating the performance of the stack 100 (and/or individual subs-stacks thereof) in a test oracle 252. The output of the test oracle 252 is informative to an expert 122 (team or individual), allowing them to identify issues in the stack 100 and modify the stack 100 to mitigate those issues (S124). The results also assist the expert 122 in selecting further scenarios for testing (S126), and the process continues, repeatedly modifying, testing and evaluating the performance of the stack 100 in simulation. The improved stack 100 is eventually incorporated (S125) in a real-world AV 101, equipped with a sensor system 110 and an actor system 112. The improved stack 100 typically includes program instructions (software) executed in one or more computer processors of an on-board computer system of the vehicle 101 (not shown). The software of the improved stack is uploaded to the AV 101 at step S125. Step S125 may also involve modifications to the underlying vehicle hardware. On board the AV 101, the improved stack 100 receives sensor data from the sensor system 110 and outputs control signals to the actor system 112. Real-world testing (S128) can be used in combination with simulation-based testing. For example, having reached an acceptable level of performance through the process of simulation testing and stack refinement, appropriate real-world scenarios may be selected (S130), and the performance of the AV 101 in those real scenarios may be captured and similarly evaluated in the test oracle 252.

### Testing Pipeline:

Further details of an example testing pipeline incorporating the test oracle 252 will now be described. The examples that follow focus on simulation-based testing. However, as noted, the test oracle 252 can equally be applied to evaluate stack performance on real scenarios, and the relevant description below applies equally to real scenarios. The following description refers to the stack 100 of FIG. 1A by way of example. However, as noted, the testing pipeline 200 is highly flexible and can be applied to any stack or sub-stack operating at any level of autonomy.

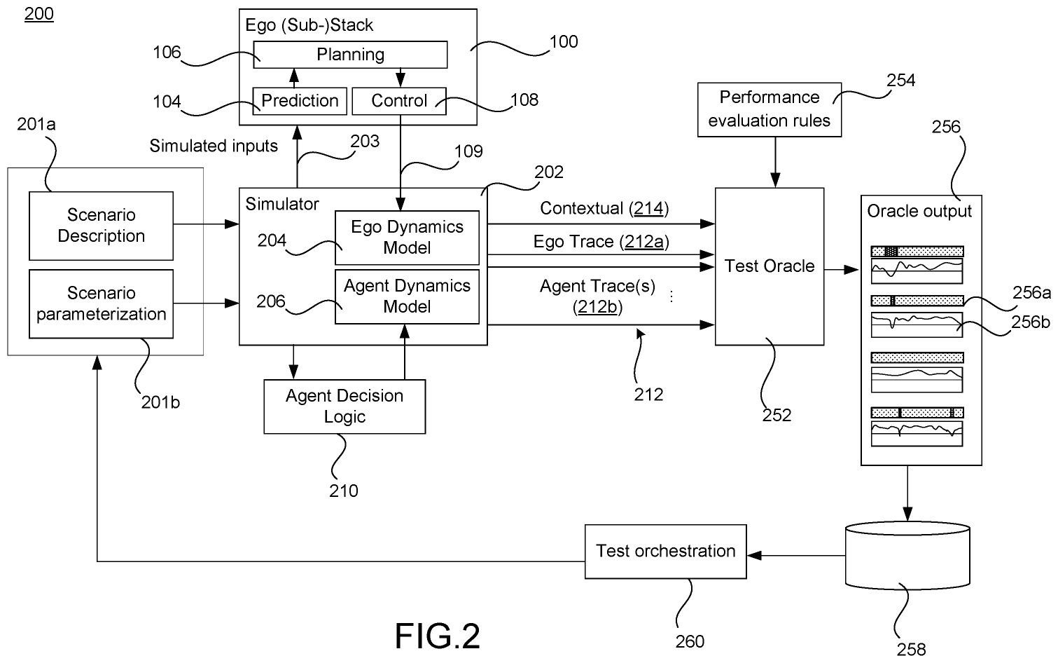

FIG. 2 shows a schematic block diagram of the testing pipeline, denoted by reference numeral 200. The testing pipeline 200 is shown to comprise the simulator 202 and the test oracle 252. The simulator 202 runs simulated scenarios for the purpose of testing all or part of an AV run time stack 100, and the test oracle 252 evaluates the performance of the stack (or sub-stack) on the simulated scenarios. As discussed, it may be that only a sub-stack of the run-time stack is tested, but for simplicity, the following description refers to the (full) AV stack 100 throughout. However, the description applies equally to a sub-stack in place of the full stack 100. The term “slicing” is used herein to the selection of a set or subset of stack components for testing.

The idea of simulation-based testing is to run a simulated driving scenario that an ego agent must navigate under the control of the stack 100 being tested. Typically, the scenario includes a static drivable area (e.g. a particular static road layout) that the ego agent is required to navigate, typically in the presence of one or more other dynamic agents (such as other vehicles, bicycles, pedestrians etc.). To this end, simulated inputs 203 are provided from the simulator 202 to the stack 100 under testing.

The slicing of the stack dictates the form of the simulated inputs 203. By way of example, FIG. 2 shows the prediction, planning and control systems 104, 106 and 108 within the AV stack 100 being tested. To test the full AV stack of FIG. 1A, the perception system 102 could also be applied during testing. In this case, the simulated inputs 203 would comprise synthetic sensor data that is generated using appropriate sensor model(s) and processed within the perception system 102 in the same way as real sensor data. This requires the generation of sufficiently realistic synthetic sensor inputs (such as photorealistic image data and/or equally realistic simulated lidar/radar data etc.). The resulting outputs of the perception system 102 would, in turn, feed into the higher-level prediction and planning systems 104, 106.

By contrast, so-called “planning-level” simulation would essentially bypass the perception system 102. The simulator 202 would instead provide simpler, higher-level inputs 203 directly to the prediction system 104. In some contexts, it may even be appropriate to bypass the prediction system 104 as well, in order to test the planner 106 on predictions obtained directly from the simulated scenario (i.e. “perfect” predictions).

Between these extremes, there is scope for many different levels of input slicing, e.g. testing only a subset of the perception system 102, such as “later” (higher-level) perception components, e.g. components such as filters or fusion components which operate on the outputs from lower-level perception components (such as object detectors, bounding box detectors, motion detectors etc.).

As an alternative to synthetic sensor data, all or part of the perception system 102 may be modelled, e.g. using one or more perception error models (PEMs) to introduce realistic error into the simulated inputs 203. For example, Perception Statistical Performance Models (PSPMs) or, synonymously, “PRISMs” may be used. Further details of the principles of PSPMs, and suitable techniques for building and training such models, may be bound in International Patent Publication Nos. WO2021037763 WO2021037760, WO2021037765, WO2021037761, and WO2021037766, each of which is incorporated herein by reference in its entirety.

Whatever form they take, the simulated inputs 203 are used (directly or indirectly) as a basis for decision-making by the planner 108. The controller 108, in turn, implements the planner's decisions by outputting control signals 109. In a real-world context, these control signals would drive the physical actor system 112 of AV. In simulation, an ego vehicle dynamics model 204 is used to translate the resulting control signals 109 into realistic motion of the ego agent within the simulation, thereby simulating the physical response of an autonomous vehicle to the control signals 109.

Alternatively, a simpler form of simulation assumes that the ego agent follows each planned trajectory exactly between planning steps. This approach bypasses the control system 108 (to the extent it is separable from planning) and removes the need for the ego vehicle dynamic model 204. This may be sufficient for testing certain facets of planning.

To the extent that external agents exhibit autonomous behaviour/decision making within the simulator 202, some form of agent decision logic 210 is implemented to carry out those decisions and determine agent behaviour within the scenario. The agent decision logic 210 may be comparable in complexity to the ego stack 100 itself or it may have a more limited decision-making capability. The aim is to provide sufficiently realistic external agent behaviour within the simulator 202 to be able to usefully test the decision-making capabilities of the ego stack 100. In some contexts, this does not require any agent decision making logic 210 at all (open-loop simulation), and in other contexts useful testing can be provided using relatively limited agent logic 210 such as basic adaptive cruise control (ACC). One or more agent dynamics models 206 may be used to provide more realistic agent behaviour if appropriate.

A scenario is run in accordance with a scenario description 201, which typically has both static and dynamic elements. The static element(s) typically include a static road layout. The dynamic element(s) typically include one or more external agents within the scenario, such as other vehicles, pedestrians, bicycles etc. Scenario runs are orchestrated by a test orchestration component 260.

The extent of the dynamic information provided to the simulator 202 for each external agent can vary. For example, a scenario may be described by separable static and dynamic layers. A given static layer (e.g. defining a road layout) can be used in combination with different dynamic layers to provide different scenario instances. The dynamic layer may comprise, for each external agent, a spatial path to be followed by the agent together with one or both of motion data and behaviour data associated with the path. In simple open-loop simulation, an external actor simply follows the spatial path and motion data defined in the dynamic layer that is non-reactive i.e. does not react to the ego agent within the simulation. Such open-loop simulation can be implemented without any agent decision logic 210. However, in closed-loop simulation, the dynamic layer instead defines at least one behaviour to be followed along a static path (such as an ACC behaviour). In this case, the agent decision logic 210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 210 might be permitted to reduce the speed of the external agent below the target at any point along the path in order to maintain a target headway from a forward vehicle.

The output of the simulator 202 for a given simulation includes an ego trace 212a of the ego agent and one or more agent traces 212b of the one or more external agents (traces 212). Each trace 212a, 212b is a complete history of an agent's behaviour within a simulation having both spatial and motion components. For example, each trace 212a, 212b may take the form of a spatial path having motion data associated with points along the path such as speed, acceleration, jerk (rate of change of acceleration), snap (rate of change of jerk) etc.

A “trace” is a history of an agent's location and motion over the course of a scenario. There are many ways a trace can be represented. Trace data will typically include spatial and motion data of an agent within the environment. The term is used in relation to both real scenarios (with real-world traces) and simulated scenarios (with simulated traces).

Additional information is also provided to supplement and provide context to the traces 212. Such additional information is referred to as “contextual” data 214. The contextual data 214 pertains to the physical context of the scenario, and can have both static components (such as road layout) and dynamic components (such as weather conditions to the extent they vary over the course of the simulation).

The test oracle 252 receives the traces 212 and the contextual data 214, and scores those outputs in respect of a set of performance evaluation rules 254. The performance evaluation rules 254 are shown to be provided as an input to the test oracle 252.

The rules 254 are categorical in nature (e.g. pass/fail-type rules). Certain performance evaluation rules are also associated with numerical performance metrics used to “score” trajectories (e.g. indicating a degree of success or failure or some other quantity that helps explain or is otherwise relevant to the categorical results). The evaluation of the rules 254 is time-based-a given rule may have a different outcome at different points in the scenario. The scoring is also time-based: for each performance evaluation metric, the test oracle 252 tracks how the value of that metric (the score) changes over time as the simulation progresses. The test oracle 252 provides an output 256 comprising a time sequence 256a of categorical (e.g. pass/fail) results for each rule, and a score-time plot 256b for each performance metric, as described in further detail later. The results and scores 256a, 256b are informative to the expert 122 and can be used to identify and mitigate performance issues within the tested stack 100. The test oracle 252 also provides an overall (aggregate) result for the scenario (e.g. overall pass/fail). The output 256 of the test oracle 252 is stored in a test database 258, in association with information about the scenario to which the output 256 pertains.

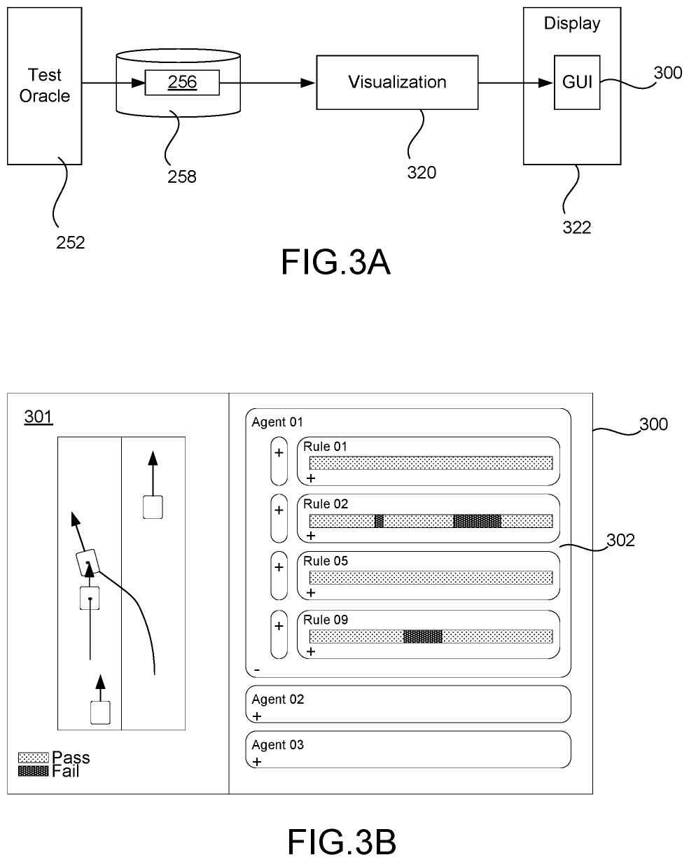

FIG. 3A shows a schematic block diagram of a visualization component 320. The visualization component 320 is shown having an input connected to the test database 258 for rendering the outputs 256 of the test oracle 252 on a graphical user interface (GUI) 300. The GUI is rendered on a display system 322.

FIG. 3B shows an example view of the GUI 300. The view pertains to a particular scenario containing multiple agents and is shown to comprise a scenario visualization 301 and a set of driving performance assessment results 302. In this example, the test oracle output 526 pertains to multiple external agents, and the results are organized according to agent. For each agent, a time-series of results is available for each rule applicable to that agent at some point in the scenario. Colour coding is used to differentiate between periods of pass/fail on a particular rule.

### Synthetic Scenario Generation:

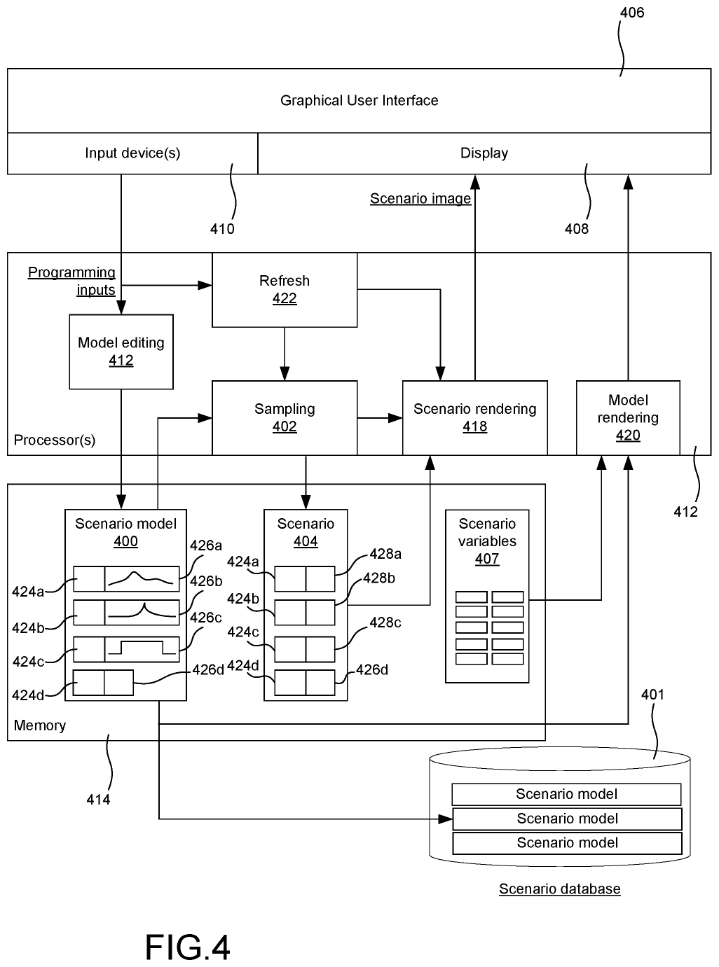

FIG. 4 shows a schematic block diagram of a computer system for editing and previewing scenario models. A graphical user interface 406 (GUI) is rendered on a display 408 (or on multiple displays), with one or more input devices 410 operable to receive user inputs to interact with the GUI 406. For conciseness, such inputs may be described as inputs received at the GUI 406 and this terminology is understood to mean inputs that are received using any form of input device 410 to interact with the GUI 406. For example, the input devices 410 may comprise one or more of a touchscreen, mouse, trackpad keyboard etc. A processor 412 is depicted, coupled to a memory 414 and to the display 408 and the input devices 410. Although a single processor 412 is shown, the functions described below can be carried out in a distributed fashion using multiple processors.

The GUI 406 allows a user to select scenario variables, from a set of available, predetermined scenario variables 407 and assign constraints to those variables. The predetermined scenario variables 407 are associated with predetermined scenario generation rules, according to which scenarios are generated, subject to any constraints placed on those variables in the scenario model.

The selected scenario variables (V) and the assigned constraints (C) are embodied in a scenario model 400. The system allows the user to assign constraints that are probabilistic in nature, allowing multiple scenarios to be sampled from the scenario model probabilistically. The scenario model 400 may be characterized as a probabilistic form of “abstract” scenario (being a more abstracted/higher-level scenario description) from which different “concrete” scenarios (less-abstracted/lower-level scenarios) may be generated via sampling. The scenario model 400 can also be characterized as a generative model that generates different scenarios with some probability. Mathematically, this may be expressed as:

s˜S(V,C),

where s denotes a scenario and S(V,C) denotes a scenario model 400 defined by a set of scenario variables V and a set of constraints C on those variables V. The probability of generating a given scenario s (characterized by values of V) given a scenario model S(V,C) is denoted P (V=s|C). In software terms, the scenario model 400 is a probabilistic computer program (coded in scenario DSL), which is executed in order to generate a scenario (with different executions generally producing different scenarios). A valid instance of the scenario is defined by a set of values s for the variables V such that the constraints C are satisfied.

The user can define scenario elements of different types (e.g. road, junction, agent etc.) and different scenario variables may be applicable to different types of elements. Certain scenario variables may pertain to multiple element types (e.g. variables such as road length, number of lanes etc. are applicable to both road and junction elements).

FIG. 4 shows a model editing component 416, a sampling component 402, a scenario rendering component 418, a model rendering component 420 and a refresh component 422. The aforementioned components are functional components representing functions that are implemented on the processor 412.

The model editing component 416 creates, in the memory 414, the scenario model 400 and modifies the scenario model 400 according to model creation inputs, which take the form of programming inputs received at the GUI 406. The scenario model 400 is stored in the form of a scenario specification, which is a DSL encoding of the selected scenario variables and their assigned constraints. Such constraints can be formulated as deterministic values assigned to scenario variables or distributions assigned to scenario variables from which deterministic values of those scenario variables can be subsequently sampled. The scenario DSL also allows constraints to be formulated in terms of relationships between different scenario variables, where those relationships may be deterministic or probabilistic in nature (probabilistic relationships may also be defined in terms of distributions). Examples of different scenario models are described in detail below.

The sampling component 402 has access to the scenario model 400 and can generate different scenarios based on the scenario model 400. To the extent the scenario variables defined in the scenario model 400 are constrained probabilistically (rather than deterministically), the generation of a scenario 404 includes the sampling of deterministic values of scenario variable(s) from associated distribution(s) that define the probabilistic constraints. By way of example, the scenario model 400 is shown to comprise first, second and third scenario variables 424a, 424b, 424c, which are associated with first, second and third distributions 426a, 426b, 426c respectively. The scenario 404 generated from the scenario model 400 is shown to comprise respective values 428a, 428b, 428c assigned to the first, second and third scenario variables 424a, 424b, 424c, which have been sampled from the first, second and third distributions 426a, 426b, 426c respectively.

As described in further detail below, a scenario variable could pertain to a road layout or a dynamic agent. For example, a road curvature variable might be assigned some distribution, from which different road curvature values may be sampled for different scenarios. Similarly, a lane number variable might be associated with a distribution, to allow scenarios with different numbers of lanes to be generated, where the number of lanes in each scenario is sampled from that distribution. An agent variable might correspond to a position or initial speed of an agent, which can be similarly assigned a distribution, from which different starting positions or speeds etc. can be sampled for different scenarios. The scenario DSL presented herein is highly flexible, allowing both deterministic and probabilistic constraints to be placed on such variables, including inter-dependency relationships between different scenario variables.

Relationships may be imposed between variables of different types, e.g. a developer could use a road layout variable to define or constrain a dynamic variable e.g. as agent_position=[0 . . . lane width].

To assist the developer (user) who is creating or editing the scenario model 400, the scenario 404 is generated in the memory 414 and provided to the scenario rendering component 418, which in turn renders a scenario visualization on the GUI 406. The scenario visualization comprises at least one image representation of the scenario 404 generated from the scenario model 400 (scenario image), which may be a static image or video (moving) image.

The scenario visualisation within the GUI 406 can be “refreshed”, which means rendering a scenario image(s) of a new scenario generated from the scenario model 400, e.g. to replace the previous scenario image(s). In this particular implementation, a visualisation of only a single scenario 404 is rendered at any one time. Because scenario variables may be defined probabilistically, the single scenario 404 will not be fully representative of the scenario model 400. However, by refreshing the scenario visualization to visualize new scenarios generated from the scenario model 400, intuitive visual feedback of the scenario model 400 is provided over time. The refresh component 422 causes the visualisation to be refreshed, by causing the sampling component 402 to generate a new scenario and the scenario rendering component 418 to render a scenario image(s) of the new scenario on the GUI 406. In this context, reference numeral 404 denotes whichever scenario is currently visualised on the GUI 406, and this scenario 404 will change as the scenario visualisation is refreshed. It will be appreciated that this is merely one possible implementation choice. For example, multiple scenarios generated from the scenario model 400 may be visually rendered simultaneously on the GUI 406 in other implementations. As another example, the scenario visualization could “morph” dynamically, showing a range of scenarios that might be generated from the scenario model 400 e.g. above some overall probability threshold.

A refresh may be instigated manually by the user at the GUI 406, for example by selecting a refresh option displayed on the GUI 406, or via some predefined keyboard shortcut, gesture etc. A refresh may alternatively or additionally be instigated responsive to the user editing the scenario model 400 (that is, in response to the programming inputs themselves). For example, the user may introduce a new scenario variable, or remove a scenario variable, change the distribution assigned to a given scenario variable, replace a distribution with a deterministic value in the scenario model 400 or vice versa etc., causing a new scenario to be generated based on the modified scenario model 400.

FIG. 4 additionally depicts a fourth scenario variable 424d in the scenario model 400, and rather than a distribution, the scenario model 400 is shown to comprise a deterministic value 426d assigned to the fourth scenario variable 424d. This deterministic value 426d is, in turn, propagated directly into the scenario 404. For as long as the fourth scenario variable 424d remains associated in the scenario model with the deterministic value 426d, every scenario 404 generated based on the scenario model 400 will assign that same deterministic value 426d to the fourth scenario variable 424d.

Dependencies between scenario variables are not depicted in the examiner of FIG. 4, but examples of scenario models with interdependent scenario variables are described below.

The model rendering component 420 renders the scenario DSL code of the scenario model 400 as text on the GUI, which is updated as the scenario model 400 is edited by the user. The GUI provides a text-based interface to allow the developer to code the scenario model 400 in text. In addition, various GUI functions are provided to assist the user. The set of available scenario variables 407 is also shown as an input to the model rendering component 420, and the available scenario variables may be rendered on the GUI 406, for example, in a drop-down list or other GUI component in which the available scenarios are rendered as selectable elements for selective inclusion in the scenario model 400. The user's code is also parsed in real-time and elements of the user's code that do not conform to the scenario DSL are automatically detected and visually marked on the GUI 406, e.g. by underlining, highlighting etc. a section of the user's code that violates one or more syntax rules of the scenario DSL, or does not otherwise conform to the syntax of the scenario DSL.

The scenario 404 could be in SDL formal (which is to say the SDL format may be generated directly from the scenario model 400), or the scenario model 404 could be encoded in some ‘intermediate’ format used for the purpose of visualization, and which can be converted to SDL format subsequently.

Once finalised, the scenario model 400 may be exported to a scenario database 401 for use in subsequent simulation-based testing.

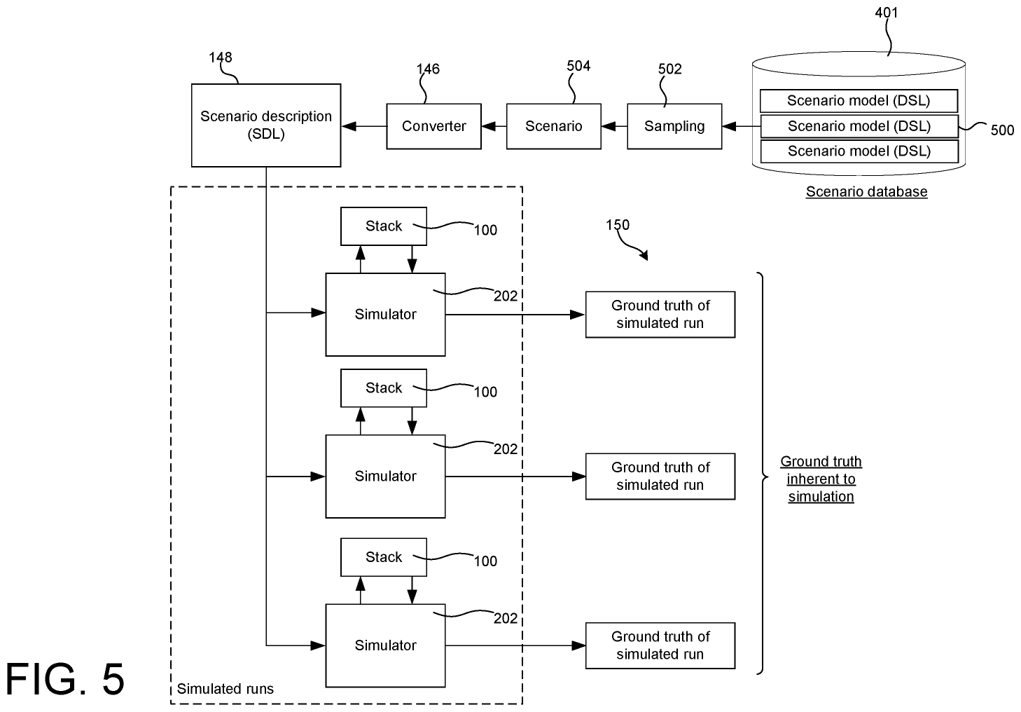

FIG. 5 shows an example AV testing pipeline that incorporates probabilistic scenario models encoded in the scenario DSL. A sampling component 502 accesses a scenario model 500 in the scenario database 401 and generates a scenario 504 based on the scenario model 500. The scenario 504 is generated from the scenario model 500 according to the same principles as FIG. 4 and involves sampling values of any probabilistic scenario variables defined in the scenario model 500. Although separate sampling components 402, 502 are depicted in FIGS. 4 and 5 respectively, these may or may not be implemented as separate functions within the system as a whole.

A converter 146 is shown, which receives the generated scenario 504 and converts it to an SDL representation 148. The SDL representation 148 is a scenario description that is consumable by the simulator 202 and may for example conform to the ASAM Open SCENARIO format or any other scenario description format conducive to simulation.

The scenario description 148 can, in turn, be used as a basis for one or (more likely) multiple simulated runs. Those simulated runs may have different outcomes, even though the underlying scenario description 148 is the same, not least because the stack 100 under testing might be different and the outcome of each simulated run depends on decisions taken within the stack 100 and the manner in which those decisions are implemented in the simulation environment. The result of each simulated run is a set of scenario ground truth 150, which in turn can be provided to the test oracle 252 of FIG. 2, in order to evaluate the performance of the stack 100 in that simulated run.

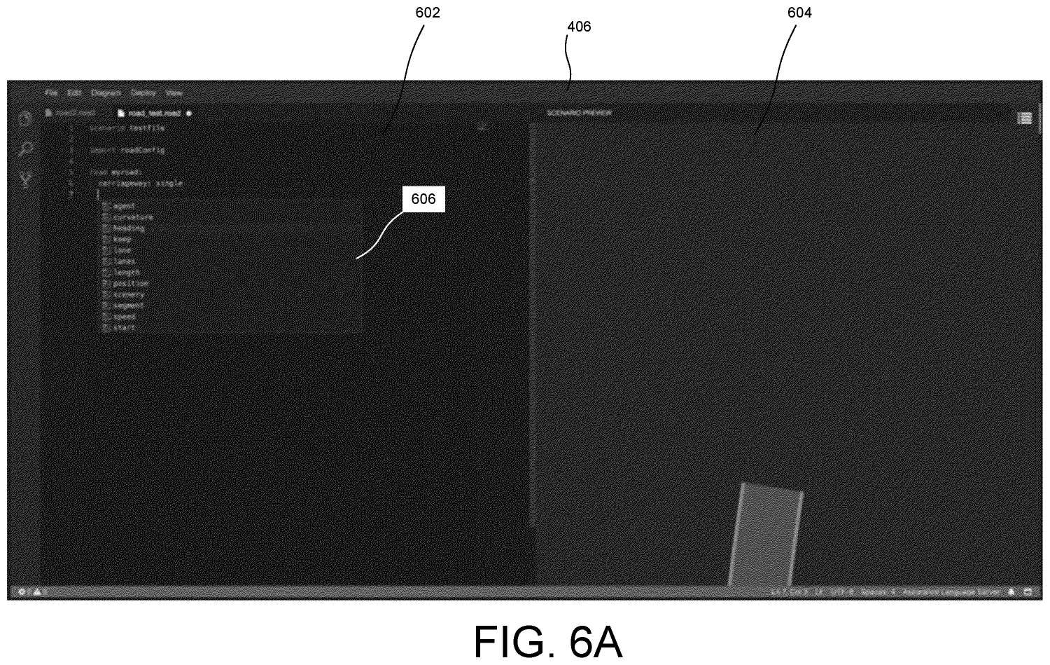

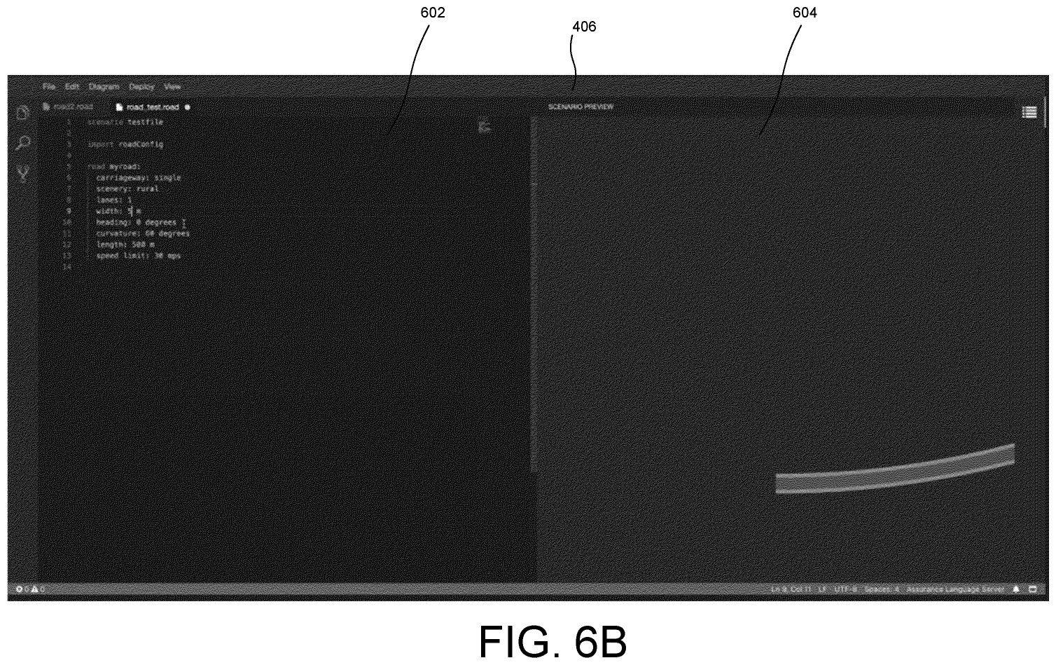

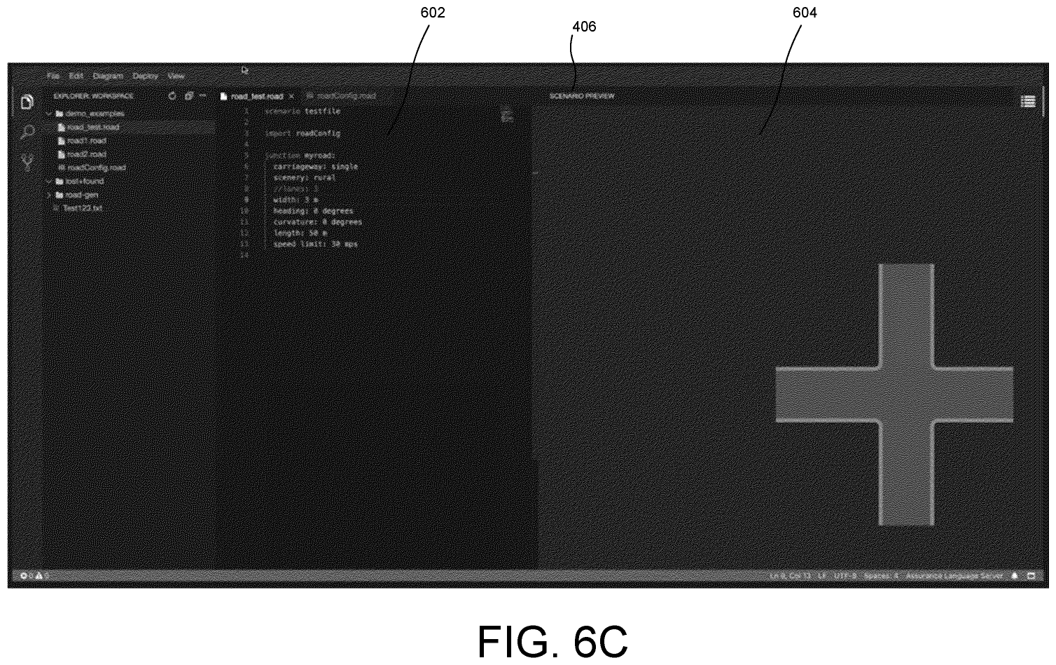

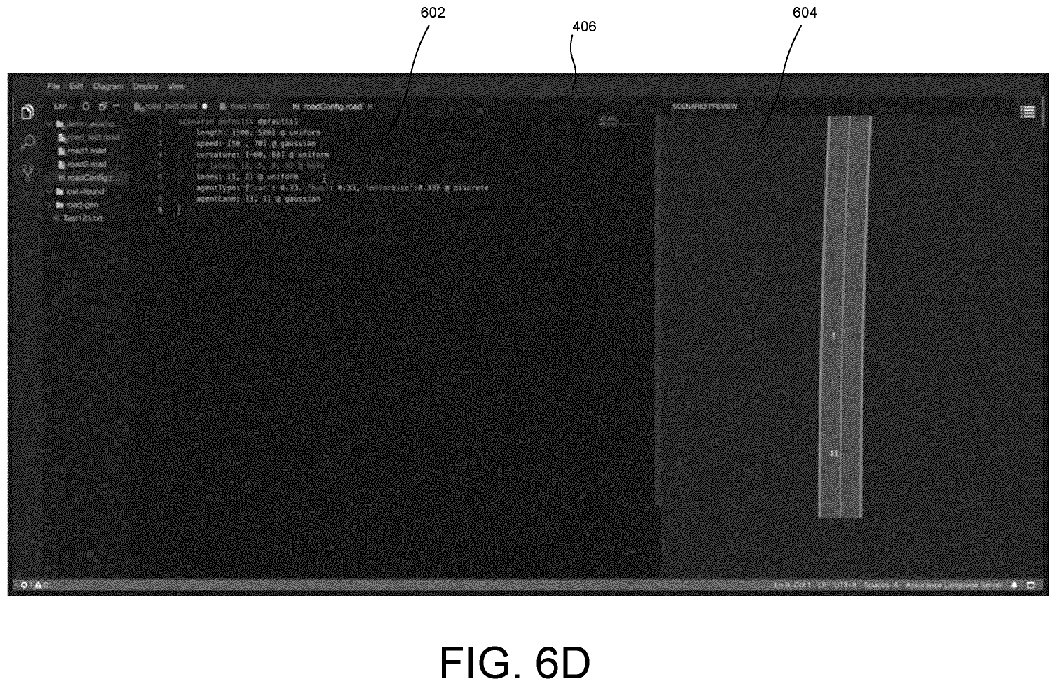

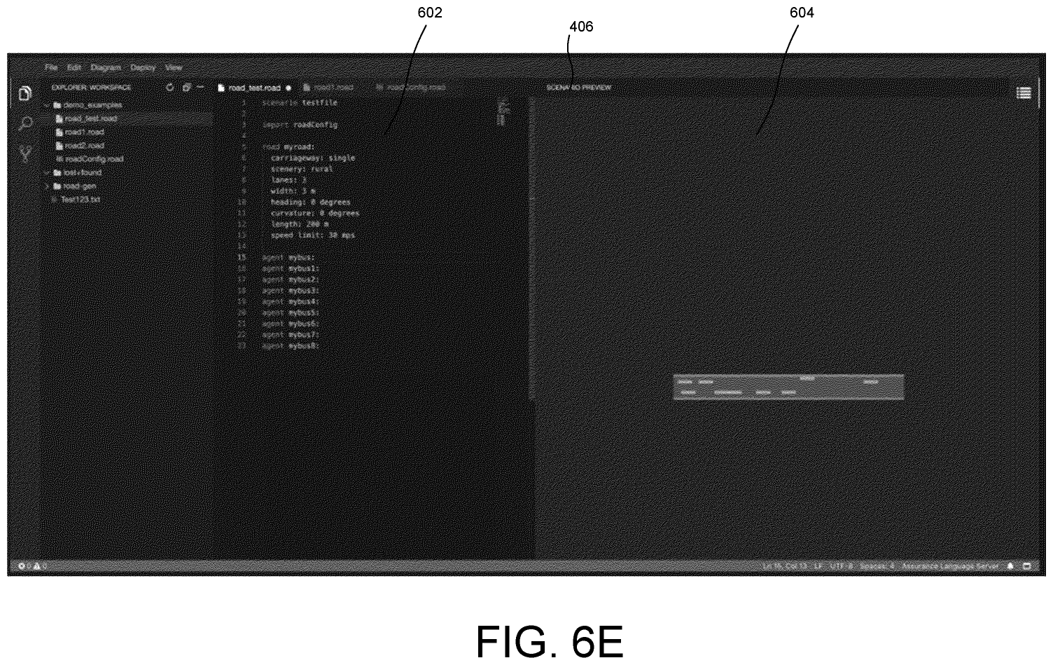

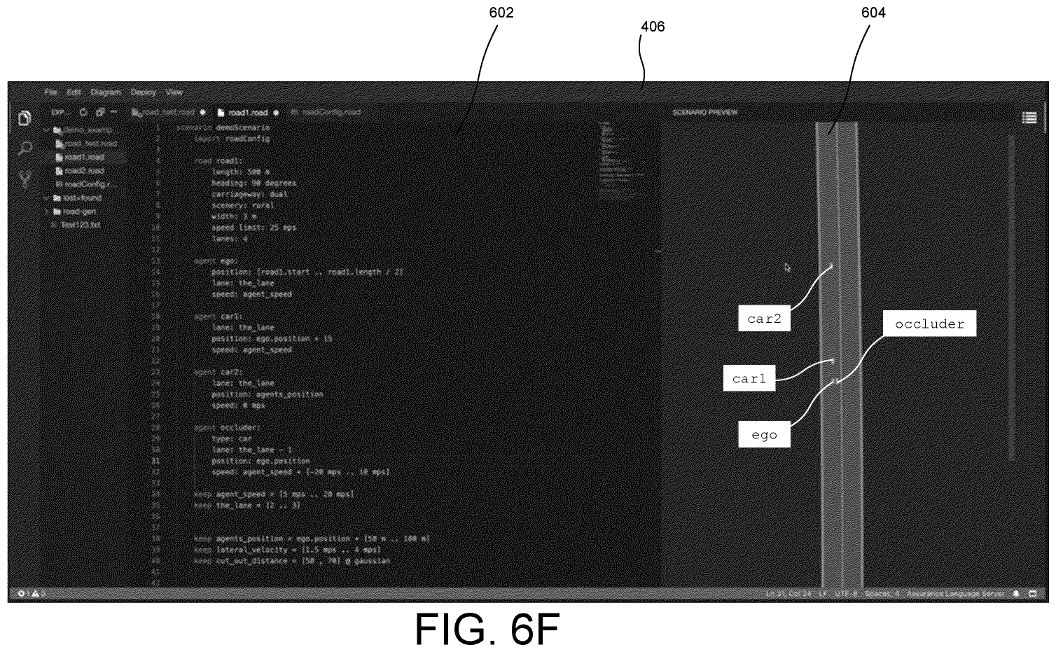

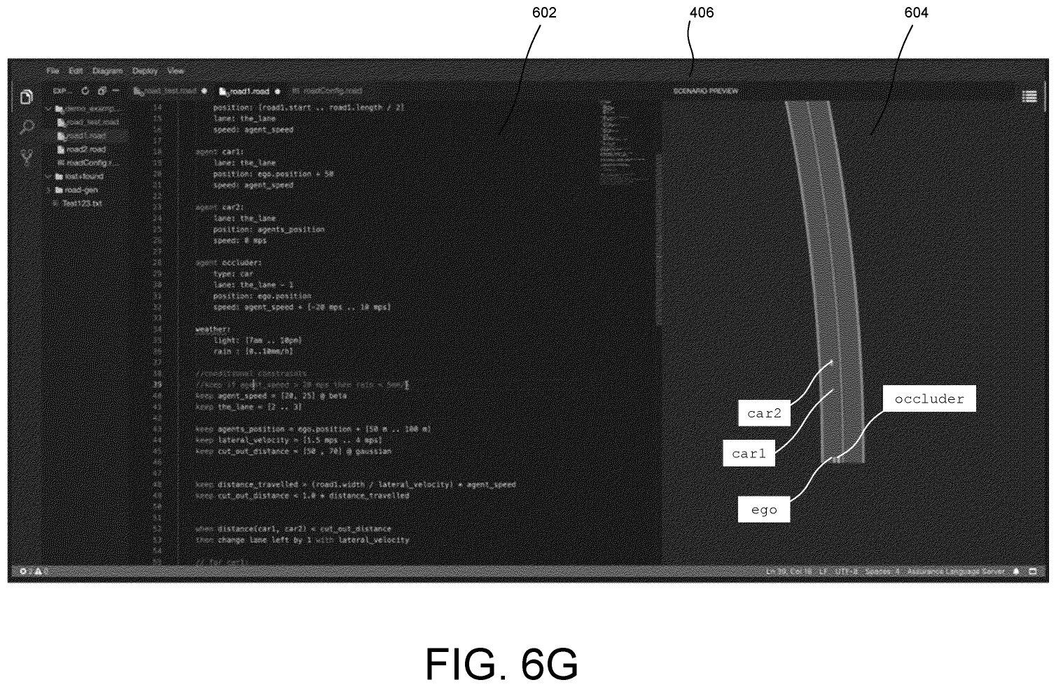

FIG. 6A shows a model editing view within the GUI 406 having a code region 602, in which scenario DSL code is displayed, and a scenario visualization region 604. Current scenario DSL code is depicted in the code region 602 and may be edited. The scenario visualization region contains an image of a scenario generated from a scenario model defined by the current code. As the code is edited, new scenarios are generated based on the modified code and visualized. In the depicted code, the user has defined a road element (line 5, “road: myroad”). A drop-down menu 606 is displayed, which contains indications of some or all of the available scenario variables (407, FIG. 4) that the user can select from.

FIG. 6B shows the model editing view at a later time, when the user has added further scenario variables and assigned deterministic values to those variables (probabilistic variables are considered below). The scenario visualization 604 has been refreshed to show a scenario image of a scenario generated based on the revised scenario model. The scenario visualization 604 continues to be refreshed as the user modifies and refines the scenario DSL, providing intuitive visual feedback about those modifications.

FIG. 6C demonstrates a notable aspect of the scenario DSL. A small modification to the code-namely changing the element type at line 5 from “road” to “junction”—has caused a material change in the scenario model, resulting in materially different scenarios.

Note that, in FIG. 6B, the user has assigned a deterministic value of 1 to a “lanes” variable (number of lanes), meaning that every scenario generated from this code will have a single lane. However, in FIG. 6B, the lanes variable has been “commented out” (meaning that it is disregarded when the scenario DSL code is executed).

The code shown in FIGS. 6A-C is contained in a scenario file, which is not a complete specification of a scenario model. Additional constraints are defined in a referenced configuration file (line 3, “import roadConfig”).

FIG. 6D shows an example configuration file rendered within the GUI 406, which can also be coded in a bespoke manner. The configuration file allows default constraints to be assigned to selected scenario variables. These default constraints may be overridden by constraints in the scenario file and will apply to the extent they are not overridden.

For example, at line 5 of the configuration file in FIG. 6D, the lanes variable is assigned to a uniform distribution on the range [1,2], using the syntax “lanes: [1,2]@uniform”. In FIG. 6B, this is overridden at line 8, which assigns the deterministic value “1” to the “lanes” variable. However, in FIG. 6C, the default constraint is not overridden, meaning that each scenario generated from the scenario model of FIG. 6C will comprise a junction having one or two lanes, each with 50% probability.

FIG. 6D shows different types of distribution (uniform, gaussian, beta, discrete) assigned to different variables, where the variables may be numerical or categorical. Numerical variables of the road layout (applicable to road and junction elements) include “length” (road length), “speed” (speed limit of a road), “curvature” (road curvature), “lanes” (number of lanes). An “agentType” variable is applicable to an agent element, and can have values of “car”, “bus” and “motorbike” in this example, each with ⅓ probability by default (discrete distribution). An “agentLane” variable describes the lane occupied by an agent, sampled from a Gaussian with mean 3 and variance 1 (syntax: “[3,1]@gaussian”) (in practice, a developer would likely select a more appropriate form of distribution for a discrete variable such as lane_id). The sampling of a distribution may be constrained by constraints (explicit or implicit) elsewhere in the code of the scenario model 400. For example, constraints such as agentLane \in [min lane id . . . max lane id] might be defined at some point in the code of the scenario model 400 that prevents sampling outside of this range (“max lane id” might, in turn, be defined in the code as some function of the number of lanes that are sampled for a given instance).

FIG. 6E shows an example of a scenario file with multiple agent elements. No variables are assigned to any of the agent elements in the scenario file, therefore all agent variables have default constraints. In this example, those constraints are probabilistic in nature, therefore agent variables such as agent position, lane and type are sampled from default distributions associated with those variables.

FIG. 6F shows how constraints may be imposed in terms of relationships/interdependencies between different scenario variables.

An ego agent is defined at lines 13 to 16, and another agent (car1) is defined at lines 18 to 21. An intermediate or “ghost” variable (“the_lane”) has been introduced by the user into the ego agent (at line15) and the car1 agent (at line 24). The ghost variable is not one of the predetermined scenario variables 407 but has been introduced in order to constrain respective “lane” variables of the different agents (the “lane” variable is one of the predetermined scenario variables 407, denoting the lane occupied by the agent in question). Whereas the predetermined scenario variables 407 directly control the process by which scenarios are generated, the intermediate “the_lane” variable does not control the scenario generation process in this example; it serves only as a “placeholder” to define constraints on selected scenario variables of the predetermined scenario variables 207.

At line 34, a probabilistic constraint is placed on “the_lane” variable, restricting it to the range [2,3]. No distribution is explicitly defined, meaning that the value of “the_lane” is sampled from the range [2,3] based on a default distribution.

Overall, the effect is that the ego agent and the car 1 agent could occupy either lane 1 or lane 2 in a generated scenario (the sampled value of “the_lane”), with some default probability, but will always occupy the same lane as each other.

The same is true of a “car2” agent defined at lines 23 to 26 (see line 24), whereas an “occlude” agent defined at lines 28 to 32, will always occupy an adjacent lane (“the_lane-1”); lane 0 if the ego, car1 and car2 agents occupy lane 1, and lane 1 if those agents occupy lane 2.

Additional ghost variables are constrained at line 34 (“agent_speed”), line 38 (“agent_position”) and line 39 (“lateral_velocity”). The “agent_speed” variable is sampled from the range [5,20] mps, and the code in lines 21 and 16 constrains the ego and car1 agents to have the same speed (equal to the sampled value of “agent_speed”). A speed variable of the occluder agent is also constrained by a combination of the distribution assigned to the “agent_speed” variable an additional distribution, as “speed: agent_speed+[−20 mps . . . 10 mps]”. To generate a scenario, a second value is sampled from the second distribution and added to the sampled value of “agent_speed”. Line 26 assigns the value “0” to the speed variable of the car2 agent, hence car2 will always be stationary.

Interdependencies can also be coded without the use of ghost variables. For example, at line 20, the position of the car1 agent is defined in terms of the position of the ego agent (ego.position) directly as “ego.position+15” (this is a deterministic relationship that would remain the same across all generated scenarios, but could be modified to be probabilistic by replacing the value “15” with a distribution).

FIG. 6G continues the example of FIG. 6F. Lines 52 and 53 of the code show how an event (in this case a lane change maneuver; see line 53) may be triggered when a triggering condition (line 52) is met. At line 45, a ghost “cut_out_distance” variable is defined and assigned a distribution from which its value is sampled. As per line 48, the change lane maneuver is triggered when the distance between car 1 and car 2 is less than the sampled value of cut_out_distance (which will be different for different scenarios). Further constraints are placed on the cut_out variable at lines 48 and 49, further restricting its possible values. In this example implementation, a “change lane left” maneuver is a behaviour that is implicitly associated with the first parameter of the “when distance (car1, car2)” element—so the “car1” agent. However, in other implementations, this may be generalized so that a maneuver of other behaviour triggered under certain condition(s) may be associated explicitly with a chosen agent(s).

Viewed as a whole, the DSL code of FIGS. 6F-G concisely defines an abstract “cut-outs” scenario, in which moving car1 changes lane as it approaches stationary car 2 (with different speeds and cut out distances), with the occluder agent driving alongside the ego agent in the adjacent lane, and with various other constraints on the road layout and the behaviour of the agents. This can be seen in the scenario visualization region 604 of FIGS. 6F and 6G; these depict different scenarios, which have been generated from the scenario model; note that the road curvature variable is not specified in the depicted code, therefore the road curvature is sampled from some default distribution.

References herein to components, functions, modules and the like, denote functional components of a computer system which may be implemented at the hardware level in various ways. A computer system comprises execution hardware which may be configured to execute the method/algorithmic steps disclosed herein and/or to implement a model trained using the present techniques. The term execution hardware encompasses any form/combination of hardware configured to execute the relevant method/algorithmic steps. The execution hardware may take the form of one or more processors, which may be programmable or non-programmable, or a combination of programmable and non-programmable hardware may be used. Examples of suitable programmable processors include general purpose processors based on an instruction set architecture, such as CPUs, GPUs/accelerator processors etc. Such general-purpose processors typically execute computer readable instructions held in memory coupled to or internal to the processor and carry out the relevant steps in accordance with those instructions. Other forms of programmable processors include field programmable gate arrays (FPGAs) having a circuit configuration programmable through circuit description code. Examples of non-programmable processors include application specific integrated circuits (ASICs). Code, instructions etc. may be stored as appropriate on transitory or non-transitory media (examples of the latter including solid state, magnetic and optical storage device(s) and the like). The subsystems 102-108 of the runtime stack FIG. 1A may be implemented in programmable or dedicated processor(s), or a combination of both, on-board a vehicle or in an off-board computer system in the context of testing and the like. The various components of FIGS. 2, 4 and 5 such as the simulator 202 and the test oracle 252 may be similarly implemented in programmable and/or dedicated hardware.

1. A computer system for generating driving scenarios for testing an autonomous vehicle planner in a simulation environment, the computer system comprising:
one or more processors; and
memory coupled to the one or more processors, the memory embodying computer-readable instructions, which, when executed on the one or more processors, cause the one or more processors to:
receive a scenario model comprising a scenario variable and a distribution associated with the scenario variable, wherein the scenario variable is a road layout variable;
compute multiple sampled values of the scenario variable based on the distribution associated the scenario variable, and
based on the scenario model, generate multiple driving scenarios for testing an autonomous vehicle planner in a simulation environment, each driving scenario comprising a road layout generated using a sampled value of said multiple sampled values of the scenario variable.

2. The computer system of claim 1, comprising:
a user interface operable to display images, wherein the computer-readable instructions cause the one or more processors to render an image of each driving scenario of the multiple driving scenarios at the user interface.

3. The computer system of claim 1, wherein the computer-readable instructions cause the one or more processors to create the scenario model according to received model creation inputs.

4. The computer system of claim 2, wherein the computer-readable instructions cause the one or more processors to create the scenario model according to received model creation inputs, and
wherein the model creation inputs are received at the user interface.

5. The computer system of claim 1, wherein the computer-readable instructions cause the one or more processors to:
receive model modification inputs,
modify the scenario model according to the model modification inputs, and
generate multiple further driving scenarios based on the modified scenario model.

6. The computer system of claim 5, wherein modifying the scenario comprises modifying the distribution associated with the scenario variable, wherein the computer-readable instructions cause the one or more processors to:
compute multiple further sampled values of the scenario variable based on the modified distribution, and
generate multiple further driving scenarios based on the modified scenario model, each further driving scenario generated using a further sampled value of the multiple further sampled values of the scenario variable.

7. The computer system of claim 1, wherein the scenario model comprises a second scenario variable and one of:
a deterministic value associated with the second scenario variable, wherein each driving scenario of the multiple driving scenarios is generated using the deterministic value of the second scenario variable,
a second distribution associated with the second scenario variable, wherein the multiple driving scenarios are generated using respective second sampled values of the second scenario variable computed based on the second distribution.

8. The computer system of claim 1, wherein the scenario model comprises a second scenario variable and an intermediate variable, wherein the distribution is assigned to the intermediate variable, and the scenario variable and the second scenario variable are defined in terms of the intermediate variable;
wherein the computer-readable instructions cause the one or more processors to:
sample multiple intermediate values of the intermediate variable from the distribution defined assigned to the intermediate variable, and
compute multiple second sampled values of the second scenario variable,
wherein each driving scenario is generated using: (i) the sampled value of said multiple sampled values of the scenario variable, that sampled value of the scenario variable being computed from an intermediate value of the multiple intermediate values of the intermediate variable, and (ii) a second sampled value of said multiple second sampled values of the second scenario variable, that second sampled value of the second scenario variable being computed from the same intermediate value of the intermediate variable.

9. The computer system of claim 1, wherein the computer-readable instructions cause the one or more processors to:
use each driving scenario of the multiple driving scenarios to generate a simulation environment, in which an ego agent is controlled by an autonomous vehicle planner user testing, and thereby generate a set of test results for assessing performance of the autonomous vehicle planner in the simulation environment.

10. The computer system of claim 1, wherein the scenario model comprises multiple scenario variables and multiple distributions, each distribution associated with at least one scenario variable.

11. The computer system of claim 1, wherein the multiple scenario variables comprise the road layout variable and a dynamic agent variable.

12. The computer system of claim 11, wherein the scenario model defines a relationship between the dynamic agent variable and the road layout variable, the relationship imposing a constraint on values that may be sampled from the distribution associated with the dynamic agent variable or the road layout variable.

13. The computer system of claim 1, comprising an autonomous vehicle (AV) planner to be tested and a simulator coupled to the AV planner, the simulator configured to run each driving scenario and determine a behaviour of an ego agent in each driving scenario to implement decisions taken by the AV planner under testing.

14. A computer-implemented method of testing an autonomous vehicle (AV) planner in a simulation environment, the method comprising:
accessing a scenario model, the scenario model comprising a set of scenario variables and a set of constraints associated therewith, the set of scenario variables comprising one or more road layout variables;
sampling a set of values of the set of scenario variables based on one or more distributions associated with the set of scenario variables, subject to the set of constraints;
generating a scenario from the set of values, the scenario comprising a synthetic road layout defined by the value(s) of the one or more road layout variables; and
testing the AV planner by running the scenario in a simulator, the simulator controlling an ego agent to implement decisions taken by a planner of the AV planner for autonomously navigating the synthetic road layout.

15. The method of claim 14, wherein the scenario model comprises a dynamic agent variable, wherein sampling the set of values of the set of scenario variables further comprises sampling a value of the dynamic agent variable, the simulator controlling behaviour of another agent based on the value of the dynamic agent variable.

16. The method of claim 14, wherein the set of constraints comprise a defined relationship between a dynamic variable and a road layout variable.

17. The method of claim 14, comprising identifying and mitigating, based on the testing, an issue in the AV planner or a component tested in combination with the AV planner.

18. A non-transitory computer readable medium embodying computer program instructions, the computer program instructions configured so as, when executed on one or more hardware processors, to implement operations comprising:
receiving a scenario model comprising a scenario variable and a distribution associated with the scenario variable, wherein the scenario variable is a road layout variable;
computing multiple sampled values of the scenario variable based on the distribution associated the scenario variable, and
based on the scenario model, generating multiple driving scenarios for testing an autonomous vehicle planner in a simulation environment, each driving scenario comprising a road layout generated using a sampled value of said multiple sampled values of the scenario variable.

19. The non-transitory computer readable medium of claim 18, wherein the one or more hardware processors implement operations comprising rendering an image of each driving scenario of the multiple driving scenarios at a user interface operable to display images.

20. The non-transitory computer readable medium of claim 18, wherein the one or more hardware processors implement operations comprising creating the scenario model according to received model creation inputs.
